(19) United States
(12) Patent Application Publication
(10) Pub. No.: US 2025/0324899 A1
(43) Pub. Date: Oct. 16, 2025

(54) MANUFACTURING METHOD OF PEROVSKITE-TYPE SOLAR CELL

(71) Applicant: TOYOTA JIDOSHA KABUSHIKI KAISHA, Toyota-shi (JP)

(72) Inventors: Toshimasa HARA, Nisshin-shi (JP); Yoichi AOKI, Kyoto-shi (JP)

(73) Assignee: TOYOTA JIDOSHA KABUSHIKI KAISHA, Toyota-shi (JP)

(21) Appl. No.: 19/006,899

(22) Filed: Dec. 31, 2024

(30) Foreign Application Priority Data
Apr. 10, 2024 (JP) 2024-063612

(51) Int. Cl. H10K 71/15; H10K 30/40; H10K 30/50; H10K 30/85; H10K 71/13; H10K 85/20

(52) U.S. Cl. CPC H10K 71/15; H10K 71/135; H10K 30/40; H10K 30/50; H10K 30/85; H10K 85/211

(57) ABSTRACT

The present disclosure relates to a manufacturing method of a perovskite-type solar cell having a photoelectric conversion layer containing a perovskite compound. The manufacturing method includes a step of applying a silver nanowire solution on an electron transport layer or a hole transport layer formed on the photoelectric conversion layer. a solvent of the silver nanowire solution is an alcohol with three or more carbon atoms.

### CROSS-REFERENCE TO RELATED APPLICATION

This application claims priority to Japanese Patent Application No. 2024-063612 filed on Apr. 10, 2024, incorporated herein by reference in its entirety.

### BACKGROUND

### 1. Technical Field

The present disclosure relates to a manufacturing method of a perovskite-type solar cell.

### 2. Description of Related Art

Solar cells are widely used as energy sources with low environmental loads. There are known, as solar cells, a silicon (Si) solar cell using silicon as a photoelectric conversion layer and a perovskite-type solar cell in which a main component of the photoelectric conversion layer is a perovskite compound.

As for a perovskite-type solar cell, for example, there is known an arrangement including a substrate, a first electrode layer, a first carrier layer (e.g., a hole transport layer or an electron transport layer), a photoelectric conversion layer, a second carrier layer (e.g., an electron transport layer or a hole transport layer), and a second electrode layer. The photoelectric conversion layer contains a perovskite compound.

A transparent conductive film is widely used as electrodes of solar cells. Known transparent conductive films include indium oxide-based (indium tin oxide (ITO), indium zinc oxide (IZO), and so forth) transparent conductive films. Indium oxide-based transparent conductive films are usually formed by sputtering.

In the manufacturing of a perovskite-type solar cell using an indium oxide-based transparent conductive film as the second electrode layer, the following processing is necessary for formation of the indium oxide-based transparent conductive film. That is to say, there is a need to form the indium oxide-based transparent conductive film by sputtering at a low temperature, such that there is no thermal damage to underlying layers, such as the photoelectric conversion layer, the electron transport layer, and the hole transport layer. However, the indium oxide-based transparent conductive film has low crystallinity in low-temperature film formation, and a low-resistance film cannot be obtained. Further, there also is concern about volatilization of film component due to subjecting the photoelectric conversion layer, which is an organic film containing the perovskite compound, to vacuum. Furthermore, sputtering has a problem of high manufacturing costs, due to being a vacuum process.

As for a transparent conductive film other than the indium oxide-based transparent conductive film, a transparent conductive film made of metal nanowires such as silver nanowires or the like is also attracting attention. The transparent conductive film made of silver nanowires can be formed by coating with a silver nanowire solution, and thus can be formed at low costs. Furthermore, the transparent conductive film made of silver nanowires has performance on the same level as that of the indium oxide-based transparent conductive film. In this way, the transparent conductive film made of silver nanowires was anticipated to be promising for solving the above-described problems regarding the indium oxide-based transparent conductive film.

Now, as described in Japanese Patent No. 6723343, silver nanowire ink usually includes a mixed solvent of water and alcohol. However, it is known that perovskite compounds have low resistance to polar solvents such as water. Accordingly, the perovskite compound in the photoelectric conversion layer deteriorates upon coming into direct contact with a polar solvent such as water, or when coming into contact with polar solvent molecules such as water or the like that has become diffused in an adjacent layer and has reached the photoelectric conversion layer. Accordingly, when a perovskite-type solar cell is manufactured using conventional silver nanowire ink, there is concern that the photoelectric conversion layer will deteriorate.

### SUMMARY

As described above, in manufacturing of a perovskite-type solar cell using conventional silver nanowire solution, there is concern that the photoelectric conversion layer will deteriorate. Accordingly, an object of the present disclosure is to provide a manufacturing method of a perovskite-type solar cell, in which deterioration of a photoelectric conversion layer can be suppressed.

The present inventors have found that deterioration of the photoelectric conversion layer can be suppressed by using a specific alcohol as a solvent of the silver nanowire solution in the manufacturing of the perovskite-type solar cell, and thus have completed the present disclosure.

That is to say, the gist of the present disclosure is as follows.

(1) A manufacturing method of a perovskite-type solar cell including a photoelectric conversion layer containing a perovskite compound, the manufacturing method including applying a silver nanowire solution onto an electron transport layer or a hole transport layer fabricated on the photoelectric conversion layer, in which a solvent of the silver nanowire solution is an alcohol with three or more carbon atoms.
(2) The manufacturing method according to the above (1), further including applying the silver nanowire solution onto an electron transport layer containing a fullerene compound, in which the solvent of the silver nanowire solution is an alcohol with five or less carbon atoms.
(3) The manufacturing method according to the above (1) or (2), further including applying the silver nanowire solution by an inkjet method, in which the solvent of the silver nanowire solution is an alcohol with four or more carbon atoms.

According to the present disclosure, a manufacturing method of a perovskite-type solar cell, in which deterioration of a photoelectric conversion layer can be suppressed, can be provided.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is an appearance photograph of a sample on which a perovskite material is deposited after immersion in each solvent for a predetermined time;

FIG. 2 is a photograph of silver nanowire layers made on a PCBM using silver nanowire ink in 1-hexanol solvent;

FIG. 3 is a flowchart showing a manufacturing process of a perovskite-type solar cell in Examples 1 and 2;

FIG. 4 is a photograph of silver nanowire layers made using silver nanowire inks in 1-butanol solvents; and

FIG. 5 is a graph showing the dielectric constant and boiling point of various solvents.

### DETAILED DESCRIPTION OF EMBODIMENTS

Hereinafter, preferred embodiments of the present disclosure will be described in detail.

The present disclosure relates to manufacturing method of a perovskite-type solar cell having a photoelectric conversion layer containing a perovskite compound.

A perovskite-type solar cell obtained by the manufacturing method of the present disclosure (hereinafter, also referred to as a solar cell of the present disclosure) has a photoelectric conversion layer containing a perovskite compound.

In one embodiment, the solar cell of the present disclosure includes a substrate, a first electrode layer (substrate-side electrode), a first carrier transport layer, a photoelectric conversion layer containing a perovskite compound, a second carrier transport layer, and a second electrode layer (counter electrode of the substrate) in this order. In this embodiment, the second electrode layer is a silver nanowire layer.

In one embodiment, the first carrier transport layer is a hole transport layer (Hole Transport Layer: HTL) and the second carrier transport layer is an electron transport layer (Electron Transport Layer: ETL). In another embodiment, the first carrier transport layer is an electron transport layer and the second carrier transport layer is a hole transport layer.

The first electrode layer and the second electrode layer may be an anode or a cathode. In one embodiment, the first electrode layer is an anode, the first carrier transport layer is a hole transport layer, the second electrode layer is a cathode, and the second carrier transport layer is an electron transport layer. In another embodiment, the first electrode layer is a cathode, the first carrier transport layer is an electron transport layer, the second electrode layer is an anode, and the second carrier transport layer is a hole transport layer.

In a first embodiment of the solar cell of the present disclosure, the solar cell includes a substrate, a first electrode layer, an electron transport layer, a photoelectric conversion layer, a hole transport layer, and a second electrode layer (silver nanowire layer) in this order.

In a second embodiment of the solar cell of the present disclosure, the solar cell includes a substrate, a first electrode layer, a hole transport layer, a photoelectric conversion layer, an electron transport layer, and a second electrode layer (silver nanowire layer) in this order.

The material of the substrate is not particularly limited. Examples of the material of the substrate include inorganic materials such as glass, organic materials such as polyethylene, polyethylene terephthalate, polyethylene naphthalate, polyimide, polyamide, polyamideimide, liquid crystal polymer, and cycloolefin polymer, and metal materials such as stainless steel and silicon. The material of the substrate is preferably glass.

The substrate may be transparent or opaque. When light is incident from the surface of the substrate, a transparent substrate is used. As the transparent substrate, a substrate made of glass, polyethylene terephthalate, polyethylene naphthalate, polyimide, polyamide, polyamide-imide, or cycloolefin polymer can be used. Also, if light is incident from the opposite side of the substrate, the substrate can be opaque. The thickness of the board is usually several tens of micrometers to several mm.

As a material of the first electrode layers, a material known as an electrode of a solar cell can be used, such as a metallic material such as aluminum (Al), silver (Ag), or gold (Au), a transparent conductive film such as indium tin oxide (ITO), indium zinc oxide (IZO), aluminum-doped zinc oxide (AZO), or fluorine-doped tin oxide (FTO), or a carbon nanotube. The material of the first electrode-layer is preferably ITO, IZO and FTO. The thickness of the first electrode-layer is usually from 50 nm to 500 nm.

The material of the second electrode layer is a transparent conductive film (silver nanowire layer) containing silver nanowires, and is preferably a transparent conductive film made of silver nanowires. The second electrode layer is formed by applying a silver nanowire solution on the electron transport layer or the hole transport layer. As the silver nanowires, for example, silver nanowires having a wire length of several μm to 100 μm and a wire diameter of several nm to several tens of nm can be used. The thickness of the second electrode-layer is usually several tens of nm to 1 micron.

The hole transport layer has a function of transporting holes generated by photoelectric conversion in the photoelectric conversion layer to the first electrode layer or the second electrode layer. As the material of the hole transport layer, a known organic material or inorganic material that can be used for the hole transport layer can be used. The organic material is not particularly limited. Examples of the organic compound include 2,2′,7,7′-tetrakis-(N,N-di-4-methoxyphenylamino)-9,9′-spirobifluorene (Spiro-OMeTAD), polyethylenedioxythiophene:polystyrenesulfonic acid (PEDOT:PSS), poly[bis(4-phenyl)(2,4,6-trimethylphenyl)amine](PTAA), [2-(3,6-dimethoxy-9H-carbazole-9H-yl)ethyl] phosphonic acid (MeO-2PACz), and the like. The inorganic material is not particularly limited, and examples thereof include nickel oxide, copper oxide, cobalt oxide, and copper iodide. In a first embodiment of the inventive solar cell, the hole transport layers are preferably Spiro-OMeTAD, PTAA and nickel-oxide. In the second embodiment of the inventive solar cell, the hole transport layers are preferably PEDOT:PSS, PTAA and nickel-oxide. The thickness of the hole transport layers is usually from 1 nm to 1000 nm.

The electron transport layer has a function of transporting electrons generated by photoelectric conversion in the photoelectric conversion layer to the first electrode layer or the second electrode layer. As the material of the electron transport layer, a known organic material or inorganic material that can be used for the electron transport layer can be used. Examples of the organic material include, but are not limited to, fullerene compounds, phenanthroline derivatives (for example, bathocuproine), polyethyleneimines, and the like. Examples of the fullerene compound include fullerenes (for example, C60 fullerenes, C70 fullerenes), derivatives obtained by adding a substituent to a fullerene (for example, methyl [6,6]-phenyl-C₆₁ butyrate (also referred to as PCBM or [60]PCBM)), methyl [6,6]-phenyl-C₇₁ butyrate (also referred to as PCBM or [70]PCBM)), and the like. Examples of the inorganic material include titanium oxide, tin oxide, and zinc oxide. In a first embodiment of the inventive solar cell, the electron transport layer is preferably made of fullerene, PCBM, bathocuproine, polyethyleneimines, titanium oxide and tin oxide. In the second embodiment of the solar cell of the present disclosure, the electron transport layer is preferably made of fullerene, PCBM, vasoxoproin, or polyethylencimine. In one embodiment, the electron transport layer contains a fullerene compound, and preferably consists of a fullerene compound. The content of the fullerene compound in the electron transport layer is usually 60% by weight or more, preferably 80% by weight or more, more preferably 90% by weight or more, particularly preferably 95% by weight or more, and most preferably 100% by weight. The thickness of the electron transport layers is usually from 1 nm to 1000 nm.

The photoelectric conversion layer contains a perovskite compound, preferably contains a perovskite compound as a main component, and more preferably consists of a perovskite compound. The content of the perovskite compound in the photoelectric conversion layer is usually 60% by weight or more, preferably 80% by weight or more, more preferably 90% by weight or more, particularly preferably 95% by weight or more, and most preferably 100% by weight. The thickness of the photoelectric conversion layers is usually 50 nm to 1000 nm, more preferably 200 nm to 600 nm.

The perovskite compound is a compound having a perovskite-type crystal structure. The perovskite crystal structure typically consists of ions A, B and X. The perovskite-type crystal structure has a cubic unit cell, A is disposed at each apex of the cubic crystal, and B is disposed at the body center, and X is disposed at each face center of the cubic crystal. The fact that the compound has a perovskite-type crystal structure can be confirmed, for example, by X-ray diffraction measurement.

The perovskite compound can be represented by the following formula (1), for example.

ABX₃ (1)

Wherein A is a monovalent cation, B is a divalent cation, and X is a monovalent anion.

In one embodiment, in Formula (1), A is at least one selected from a monovalent organic ammonium ion, a monovalent amidinium-based ion, and a monovalent metal ion. Examples of the monovalent organic ammonium ion include CH₃NH₃⁺ (methylammonium ion: MA), C₂H₅NH₃⁺, C₃H₇NH₃⁺, and C₄H₉NH₃⁺. Examples of the monovalent amidinium-based ion include HC (NH₂)₂⁺ (formamidinium ion: FA). Examples of monovalent metallic ions include rubidium ions (Rb⁺) and cesium ions (Cs⁺). In Formula (1), A may be a combination of a monovalent organic ammonium ion, a monovalent amidinium-based ion, and a monovalent metal ion. In the formula (1), A is preferably MA, FA or Cs⁺, or a combination of two or three thereof. When A contains Rb⁺or Cs⁺, the content of Rb⁺ or Cs⁺ relative to the total amount of A is usually 10 atomic % or less.

In one embodiment, in equation (1), B is a binary metal ion, e.g., a lead ion (Pb₂⁺), a tin ion (Sn₂⁺) and a combination thereof, more preferably a Pb₂⁺.

In one embodiment, in Formula (1), X is a halogen ion. For example, X is at least one selected from fluoride ion (F⁻), chloride ion (Cl⁻), bromide ion (Br), and iodide ion (I⁻). X is preferably Cl⁻, Br and I⁻.

The inventive solar cells can be used alone or in conjunction with other solar cells, such as silicon (Si) solar cells. When used in combination with other solar cells, for example, a tandem solar cell in which other solar cells are stacked on the second electrode layer (counter electrode of the substrate) side of the solar cell of the present disclosure can be used.

A manufacturing method a perovskite-type solar cell of the present disclosure includes a step of applying a silver nanowire solution on an electron transport layer or a hole transport layer (second carrier transport layer). As described above for the solar cell of the present disclosure, the electron transport layer or the hole transport layer is formed on the photoelectric conversion layer. Note that the electron transport layer or the hole transport layer may be directly laminated on the photoelectric conversion layer, or may be laminated on the photoelectric conversion layer via another layer.

The silver nanowire solution can be applied onto the electron transport layer or the hole transport layer by a known method. The method of applying the silver nanowire solution is not particularly limited. Examples of the method for applying the silver nanowire solution include a spin coating method, an inkjet method, a spray method, a blade coating method, and a die coating method. As a method of applying the silver nanowire solution, an inkjet method and a spray method are preferable, and an inkjet method is more preferable.

The application of the silver nanowire solution can usually be carried out at 15° C. to 35° C. in air.

The silver nanowire solution is prepared by dissolving or dispersing the silver nanowires in a solvent. The wire length and wire diameter of the silver nanowires are as described above for the silver nanowire layer. The concentration of the silver nanowires in the silver nanowire solution is usually 5% by weight or less, preferably 1% by weight or less. In one embodiment, when the silver nanowire solution is applied by an inkjet method, the concentration of the silver nanowires in the silver nanowire solution is preferably 0.5 wt % or less.

The solvent of the silver nanowire solution is an alcohol having 3 or more carbon atoms. By using an alcohol having 3 or more carbon atoms as a solvent for the silver nanowire solution, deterioration of the photoelectric conversion layer existing in the electron transport layer or the hole transport layer under which the silver nanowire solution is applied is suppressed. The alcohol having 3 or more carbon atoms as the solvent of the silver nanowire solution may be a monohydric or polyhydric alcohol, but is preferably a monohydric alcohol because deterioration of the photoelectric conversion layer can be further suppressed. The alcohol having 3 or more carbon atoms as the solvent of the silver nanowire solution may be either a linear alcohol or a branched alcohol, or may be either a saturated alcohol or an unsaturated alcohol. The solvent of the silver nanowire solution is preferably an alcohol having 6 or less carbon atoms. The solvent of the silver nanowire solution is preferably an alcohol having 3 or more and 6 or less carbon atoms, and more preferably 1-propanol, 1-butanol, 1-pentanol and 1-hexanol. The alcohol may be used alone or in combination of two or more.

In one embodiment, when the electron transport layer contains a fullerene compound, the solvent of the silver nanowire solution is preferably an alcohol having 5 or less carbon atoms (i.c., an alcohol having 3 or more and 5 or less carbon atoms). The solvent of the silver nanowire solution is more preferably 1-propanol, 1-butanol and 1-pentanol. When the solvent of the silver nanowire solution is an alcohol having 3 or more and 5 or less carbon atoms, deterioration of the photoelectric conversion layer and the electron transport layer can be suppressed.

In one embodiment, when the silver nanowire solution is applied by the inkjet method, the solvent of the silver nanowire solution is preferably an alcohol having 4 or more carbon atoms from the viewpoint of suppressing clogging of the inkjet nozzle.

In one embodiment, when the electron transport layer comprises a fullerene compound and the silver nanowire solution is applied by an inkjet method, the solvent of the silver nanowire solution is preferably the following solvent. From the viewpoint of suppressing deterioration of the photoelectric conversion layer and the electron transport layer and suppressing clogging of the inkjet nozzle, the solvent of the silver nanowire solution is preferably an alcohol having 4 to 5 carbon atoms. The solvent of the silver nanowire solution is more preferably 1-butanol and 1-pentanol.

The manufacturing method of the present disclosure may include a step of drying the coated silver nanowire solution. The drying step can be performed by heating at 80° C. to 150° C. in general.

In the manufacturing method of the present disclosure, a layer other than the silver nanowire layer can be formed by forming a film by a known method.

Hereinafter, the present disclosure will be described in more detail with reference to Examples. However, the technical scope of the present disclosure is not limited to these examples.

### Solvent Study of Silver Nanowire Ink 1

Solvents of silver nanowire inks applicable to photoelectric conversion layers containing perovskite compounds were investigated. As solvents, dimethyl sulfoxide (DMSO), N-methyl-2-pyrrolidone (NMP), N,N-dimethylformamide (DMF), water, methanol, ethanol, 1-propanol, 1-butanol, 1-pentanol and 1-hexanol were used.

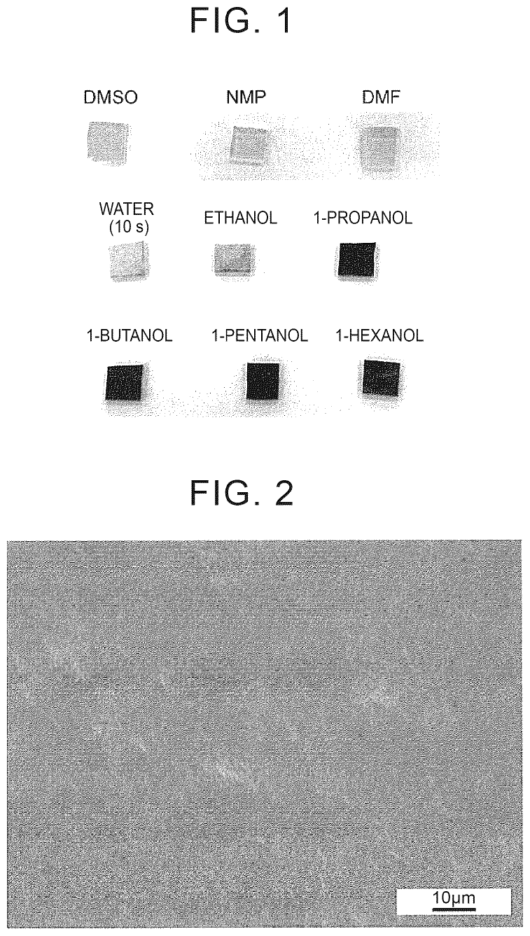

A perovskite (CsFAMAPbI₃) was deposited on the glass-substrate, and the small pieces were used as samples. The sample was immersed in each solvent and the change in appearance after 10 minutes was observed. When the solvent was water, a change in appearance after 10 seconds was observed. FIG. 1 shows an appearance photograph of a sample on which a perovskite material is formed after immersion in each solvent for a predetermined time. As shown in FIG. 1, the perovskite was dissolved in DMSO, NMP and DMF immediately after immersion. The perovskite material was yellowed by immersion in water, methanol (not shown) and ethanol for a short period of time. It is believed that the perovskite compound decomposed to form yellow lead iodide. On the other hand, in the perovskite material, even when the perovskite material was immersed in an alcohol having 3 or more carbon atoms (1-propanol, 1-butanol, 1-pentanol, and 1-hexanol) for 10 minutes, there was no change in appearance. Therefore, it was confirmed that the perovskite material is sufficiently resistant to alcohols having 3 or more carbon atoms.

### Solvent Study of Silver Nanowire Ink 2

Solvents of silver nanowire inks applicable to electron transport layers comprising [6,6]-phenyl-C₆₁ butyrate (PCBM) were investigated. Various primary alcohols were used as solvents for silver nanowire inks. First, silver nanowire inks in which silver nanowires were dispersed in various primary alcohols were prepared. Next, silver nanowire ink was applied onto PCBM by spin-coating, and the presence or absence of erosion on the underlying PCBM was confirmed by optical microscopy. The dissolution of PCBM was confirmed when the solvent of the silver nanowire ink was 1-hexanol. FIG. 2 shows an external photograph of silver nanowire layers made using silver nanowire ink in 1-hexanol solvent on a PCBM. As shown in FIG. 2, when the solvent of the silver nanowire ink was 1-hexanol, it was confirmed that there were a large number of pores in PCBM of the substrate. On the other hand, alcohols with a carbon-number of 5 or less had no effect on PCBM.

### Production of Perovskite-Type Solar Cell

### Example 1

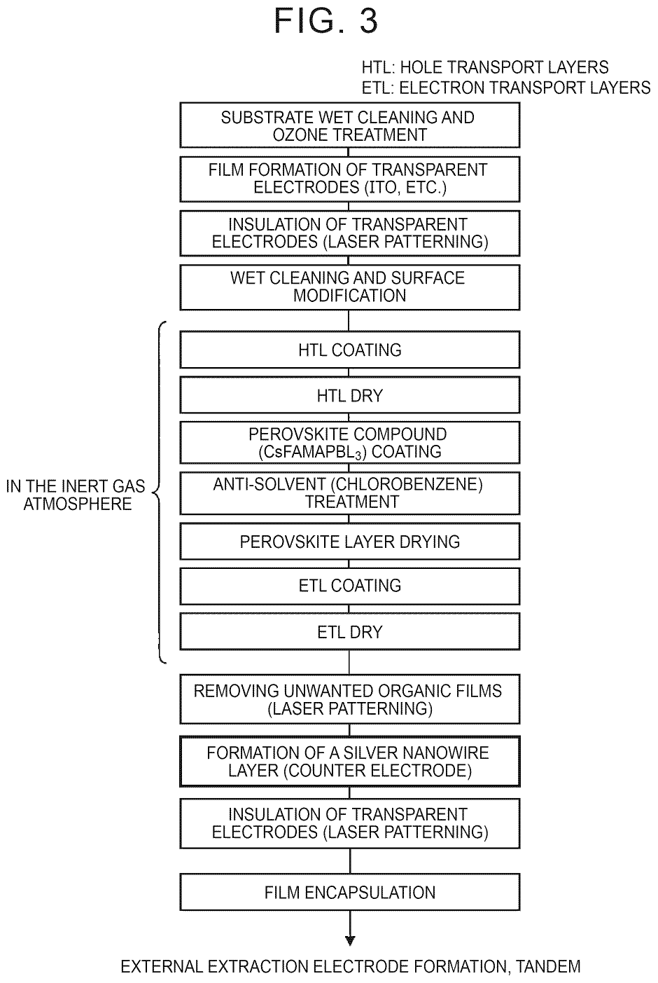

A perovskite-type solar cell was fabricated by the process shown in FIG. 3.

The perovskite layer (photoelectric conversion layer), the electron transport layer (ETL), and the silver nanowire layer (counter-electrode) were prepared as follows.

### Perovskite Layer

CsFAMAPbI₃ solutions were prepared and chlorobenzene was used as an anti-solvent. First, spin-coated CsFAMAPbI₃ solutions were applied onto a hole transport layer (HTL) and then anti-solvent was applied. Thereafter, the mixture was heated in a hot plate at 100° C. for 1 hour, and dried.

### Electron Transport Layers (ETL)

[6,6]-Phenyl-C61-methyl butyrate (PCBM) (Pure by P2682 (HPLC manufactured by Tokyo Chemical Industry Co., Ltd.: >99.5%) was dissolved in 1-chlorobenzene to prepare PCBM inks having 30 mg/ml densities. PCBM ink was spin-coated on the perovskite layer at a rotational speed 1000 rpm for 30 seconds, heated on a hot plate at 100° C. for 10 minutes, and dried.

### Silver Nanowire Layer (Counter Electrode, Transparent Electrode)

Silver nanowire ink (manufactured by Hoshi PMC Co., Ltd., wire length: 4 μm, wire diameter: 25 nm, solvents: 1-butanol (purity: >95%), solid content: ≤1 wt %) was spin-coated on a ETL at a rotational speed 1000 rpm for 10 seconds, and heated on a hot plate at 100° C. for 5 minutes to dry.

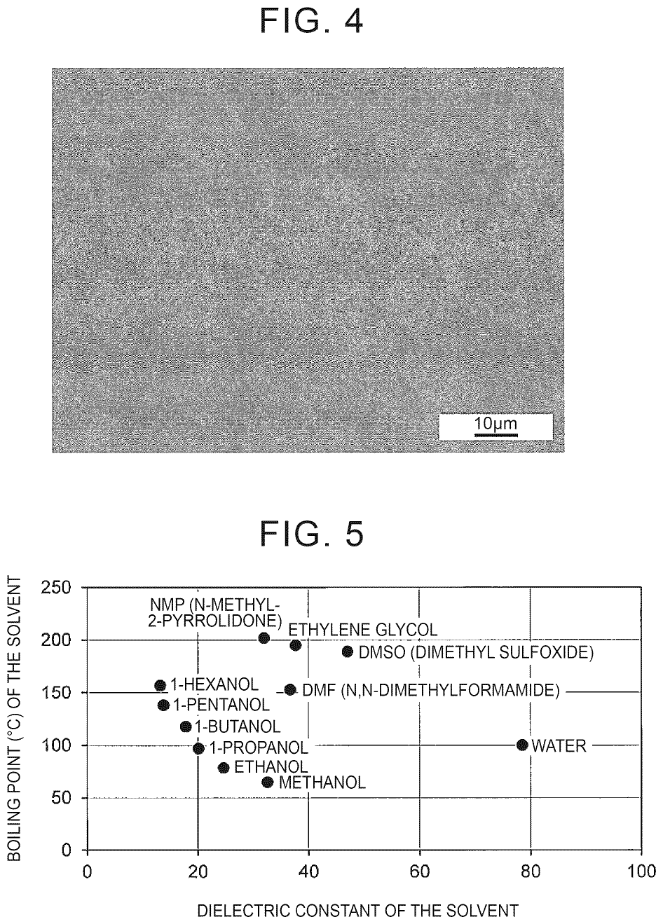

The silver nanowire layer of the obtained solar cell was observed by an optical microscope. FIG. 4 shows an appearance photograph of a silver nanowire layer prepared using a silver nanowire ink of 1-butanol solvent. As shown in FIG. 4, when the solvent of the silver nanowire ink was 1-butanol, it was confirmed that the resulting silver nanowire layers had no aggregation or anisotropy of the nanowires and no dissolution of PCBM.

### Example 2

For the cells using the perovskite layer and ETL similar to those of the first embodiment, the silver nanowire layer was formed by an inkjet method by changing the solvents of the silver nanowire ink. The silver nanowire ink was prepared in the same manner as the silver nanowire ink used in Example 1, except that the solvent was changed to 1-pentanol (>95%) or 1-propanol (>95%) and the solids concentration was changed to ≤0.5 wt %.

FIG. 5 shows the dielectric constant and boiling point of various solvents. In FIG. 5, the dielectric constant indicates the relative dielectric constant at 20° C. As confirmed in Study 1 of the solvent of the silver nanowire ink, it has been confirmed that the perovskite material is sufficiently resistant to alcohols having 3 or more carbon atoms. Here, in the inkjet method, since clogging of the inkjet nozzle can be suppressed by using a solvent having a higher boiling point, it is considered desirable to use a solvent having a boiling point of 100° C. or higher as a reference. However, even when 1-propanol having a boiling point slightly lower than 100° C. was used as a solvent for the silver nanowire ink, the silver nanowire layer was formed by the inkjet method, and thus a solar cell could be produced. In addition, even when 1-pentanol was used as a solvent for silver nanowire ink, a silver nanowire layer was formed by an inkjet method, and a solar cell could be produced.

What is claimed is:

1. A manufacturing method of a perovskite-type solar cell including a photoelectric conversion layer containing a perovskite compound, the manufacturing method comprising applying a silver nanowire solution onto an electron transport layer or a hole transport layer fabricated on the photoelectric conversion layer, wherein a solvent of the silver nanowire solution is an alcohol with three or more carbon atoms.

2. The manufacturing method according to claim 1, further comprising applying the silver nanowire solution onto an electron transport layer containing a fullerene compound, wherein the solvent of the silver nanowire solution is an alcohol with five or less carbon atoms.

3. The manufacturing method according to claim 1, further comprising applying the silver nanowire solution by an inkjet method, wherein the solvent of the silver nanowire solution is an alcohol with four or more carbon atoms.
